(19) United States
(12) Patent Application Publication
(10) Pub. No.: US 2003/0048157 A1
(43) Pub. Date: Mar. 13, 2003

(54) Molded common mode ferrite filter for electronic sensors

(76) Inventors: Lamar Floyd Ricks, Freeport, IL (US); John Angelo Modica, Lena, IL (US)

Correspondence Address: HONEYWELL INTERNATIONAL INC., 101 COLUMBIA ROAD, P O BOX 2245, MORRISTOWN, NJ, 07962-2245, US

(21) Appl. No.: 09/951,800

(22) Filed: Sep. 10, 2001

(51) Int. Cl. H03H 7/01

(52) U.S. Cl. 333/181; 333/185

(57) ABSTRACT

A method for forming a common mode filter for an electronic sensor and a common mode filter apparatus thereof is disclosed. A common mode filter may be molded across electrical conductors associated with the electronic sensor to thereby provide an enhanced EMC performance for the electronic sensor. The common mode filter is thus integrated with the electronic sensor rather than implemented as a separate common mode filter component. The common mode filter may comprise a ferrite filter molded across the electrical conductors associated with the electronic sensor. The electrical conductors may comprise electrical components such as, for example, a leadframe or leadwires associated with the electronic sensor. Additionally, the common mode filter can be configured as a pre-molded tie bar. Such a pre-molded tie bar may be configured as a ferrite tie bar.

### BACKGROUND OF THE INVENTION

Electromagnetic fields exist naturally in nature and are also generated in electromagnetic equipment operated in our environment. In a broad sense, an electromagnetic field is in a category of fields that contain electrical and magnetic components over a wide range of frequencies, including those in the microwave and radio frequency (RF) ranges. Electromagnetic interference (EMI) is a common problem in modern telecommunications, computer and industrial control equipment. Because of this electromagnetic interference, connectors are required to provide electrical shielding as well as filtering of electrical signals of unwanted high frequency harmonics.

There are many known techniques for suppressing electromagnetic interference (EMI) from a system, such as a computer system to contain or diminish stray noise signals. Systems such as computer systems typically need to comply with an electromagnetic compliance (EMC) standard, which defines limits to levels of stray EMI noise signals. Thus, the design goal of an EMC solution is to design a system with stray EMI noise signal levels below the EMC standard limit while minimizing the cost of compliance.

Active circuits, including active audio components found in audio entertainment equipment, are circuits that are exposed to and/or generate electromagnetic fields. Active circuits, by their nature, generate EMI. As an example, active circuits as they relate to active audio components include, but are not limited to, pre-amplifiers, power amplifiers, compact disc (CD) players, both integrated and separate transports, digital-to-analog converters, interface devices, turntables, audio tape recorders and the like. Thus, any active audio component that can self-generate or function as an antenna for RF, microwave, electric or magnetic spurious fields can generate EMI.

EMI generally results from the negative interaction of these spurious fields with the transfer function of active signal path circuitry. These spurious RF, microwave, electric and magnetic fields radiate from several millimeters to several feet around the chassis of an active audio component, referred to as the host component. Left unaftenuated, undesirable components of the electromagnetic field can propagate back into the active circuits of the host component, generating noise artifacts that are amplified with the music waveform. This action can result in a noisier, grainier background signal level during periods of inter-transient silence and a reduction in dynamic contrasts as audio signal levels change. By reducing these noise sources, the overall reproduction of the music becomes more detailed, encompassing greater stage depth, width and clarity.

The category of EMI includes what is identified as “parasitic oscillations”, which are subtle but audible noise components. These extremely short, tiny bursts of energy are visible on high-resolution waveform monitors at certain points along the cycle of a sine wave. Often originating in the RF region of the electromagnetic spectrum, they are accompanied by harmonics that reflect up and down into the audio bands and become amplified at high levels along with the music waveform. The parasitic oscillations can also be external in origin since circuit stages and circuit path traces serve as a giant maze antenna. For example, metropolitan areas are teeming with radio frequency interference (RFI) ranging in frequency from 30-Hz to 7-GHz. Automotive ignition noise dominates this category but occasionally is superseded by power distribution lines. Other sources of RFI include appliances, automotive applications and devices thereof, electric motors, fluorescent lights, electric light dimmers and door openers, industrial equipment and microwave appliances.

In active audio components, self-generated parasitic oscillations are known to occur in switching power supplies. Also, capacitive input design power supplies produce 120-Hz current “spikes” caused by rectifier conduction. Common rectifier diodes utilized in many different types of equipment generate high levels of RFI. Harmonics of these current “spikes” and bursts can be detected in a wide spectrum up to 2-MHz. Radiations of these pulses are conducted to other circuit parts within the amplifier, increasing the noise level as a result of being amplified in combination with the desired music signal. In effect, there are a number of parasitic oscillation transmitters within amplifiers that can produce broad bandwidth, multiple harmonic pulses each second.

Printed circuit boards (PCBs) are also sources of undesirable EMI. Several reasons that PCBs are sources of EMI include common impedance coupling via power and ground signal path traces, antenna loops formed by integrated circuits and their bypass capacitors, and interaction between the electromagnetic fields of adjoining signal path traces of individual or adjacent PCBs. Further, evidence suggests that poorly soldered or cold solder connections and dissimilar adjacent metals can be sources of interference. Digital equipment is also sensitive to the presence of EMI. Clock frequency division circuits and fast logic chips are adversely affected if undesirable oscillations interfere with their exacting processing circuits. These types of circuits are included, for example, within digital-to-analog converters located within compact disc players. Thus, the crux of the parasitic oscillations problem and the resulting EMI as it relates to active audio components is the production of additional noise, which is amplified along with the desired music waveform.

Several traditional approaches have been employed in the past to reduce the external RFI that propagates to active audio components. Examples include utilizing extensive chassis shielding, ferrite bead-type filters at the input and output sections and power line conditioners. The length of signal path traces is usually kept short to minimize stray inductances and capacitances, which can cause signals to ring and to overshoot or undershoot steady state voltage levels, each of which can be a source of EMI. It is known in the art to place ferrite bead devices around system interconnects to filter RFI that could enter at the interconnect points. This method is effective in reducing RF that can enter through exterior wiring. However, this method neither attenuates self-generated sources within the active audio component nor reduces high frequency microwave fields. Furthermore, ferrite material filters are generally applicable to situations in which the ferrite filter can be placed around a wire to facilitate the impedance shifting effect, which is central to the ferrite design.

Electronic sensors are thus designed for applications that must meet very difficult EMC specifications. When EMC issues arise, particularly in applications such as, for example, automotive sensor designs, a typical solution may involve making modifications to the existing filtering or adding additional filtering. Solutions might include adding components, such as ferrite beads, filter capacitors or chokes, depending on the available space on the PCB and the various failure modes that may occur. Often, however, sufficient room is not available on the existing PCB and the luxury of adding surface mount components to the PCB to solve the EMC issue simply might not exist in a given situation. The next step may be to add an external filter across all of the electrical conductors, such as a common mode ferrite filter, but the process of adding this component may severely affect the component design and it just may not be a cost-effective solution.

The present inventors have thus concluded, based on the foregoing, that a need exists for a cost-effective design for reducing EMC problems associated with electronic sensors, while permitting the utilization of an integrated common mode filter with the electronic sensors. In particular, the present inventors have concluded that such a design provides a great number of benefits to a variety of sensor applications, such as, for example, automotive sensor applications and designs thereof. The present invention disclosed herein solves these problems through a unique method and apparatus involving molded common mode ferrite filters for electronic sensors.

### BRIEF SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide improved electronic sensors.

It is another aspect of the present invention to provide an improved method and apparatus for enhancing the electromagnetic compliance (EMC) abilities of electronic sensors.

It is yet another aspect of the present invention to provide a method for forming a common mode filter for an electronic sensor, including a common mode ferrite filter.

It is still another aspect of the present invention to provide an improved common mode filter apparatus configured as a common mode ferrite filter.

The above and other aspects can be achieved as is now described. A method for forming a common mode filter for an electronic sensor and a common mode filter apparatus thereof are disclosed herein. A common mode filter is molded across electrical conductors associated with the electronic sensor to thereby provide an enhanced EMC performance for the electronic sensor. The common mode filter can thus be integrated with the electronic sensor rather than implemented as a separate common mode filter component. The common mode filter comprises a ferrite filter molded across the electrical conductors. The electrical conductors themselves can be configured as electrical components such as, for example, a leadframe or leadwires associated with the electronic sensor. Additionally, the common mode filter can be configured as a pre-molded tie bar. Such a pre-molded tie bar can be configured if desired as a ferrite tie bar.

The method and apparatus disclosed herein thus provides a very cost-effective design because standard-manufacturing processes can be utilized and require fewer changes to be incorporated into an electronic sensor design versus utilizing a separate common mode filter component. In particular, the present invention is applicable to automotive sensor designs and other similar sensor applications. Utilizing a molded ferrite filter across electrical conductors can provide an enhanced EMC performance for the electronic sensor rather than utilizing other filter components on a PCB (printed circuit board). Additionally, the molded ferrite filter can function as a pre-molded tie bar, thereby achieving two functions from a single integrated common mode filter configuration.

### BRIEF DESCRIPTION OF THE DRAWINGS

The accompanying figures, in which like reference numerals refer to identical or functionally-similar elements throughout the separate views and which are incorporated in and form part of the specification, further illustrate the present invention and, together with the detailed description of the invention, serve to explain the principles of the present invention.

FIG. 1 depicts a top view of a leadframe, in accordance with a preferred embodiment of the present invention;

FIG. 2 illustrates a side view of the leadframe illustrated in FIG. 1, in accordance with a preferred embodiment of the present invention;

FIG. 3 depicts a pictorial perspective view of the leadframe illustrated in FIGS. 1 and 2, in accordance with a preferred embodiment of the present invention;

FIG. 4 illustrates a front view of the leadframe illustrated in FIGS. 1 to 3, in accordance with a preferred embodiment of the present invention; and

FIG. 5 depicts a back view of the leadframe illustrated in FIGS. 1 to 3, in accordance with a preferred embodiment of the present invention.

### DETAILED DESCRIPTION OF THE INVENTION

The particular values and configurations discussed in these non-limiting examples can be varied and are cited merely to illustrate embodiments of the present invention and are not intended to limit the scope of the invention.

Electronic sensors are often designed for applications that must meet very difficult EMC specifications. In particular, in automotive sensor applications and designs thereof, EMC issues are extremely important. When EMC issues do arise, a typical solution involves making modifications to the existing filtering or adding additional filtering, such as ferrite beads, filter capacitors or chokes depending on the available space on the PCB and the various failure modes that can occur. Often, however, sufficient room is unavailable on the existing PCB and the luxury of adding surface mount components to the PCB to solve the EMC issue might not exist. The next logical step may be to add an external filter across all of the electrical conductors, such as a common mode ferrite filter; but the process of adding this component may severely affect the component design and is generally not a cost-effective solution.

Ferrite magnets can generally be molded as a standard product utilizing injection molded processes. It is important to note, however, that the ferrite material utilized for magnets does not posses the appropriate material properties to yield a good common mode filter. The present inventors have realized that the ferrite powder materials that do have the appropriate material properties can generally be purchased from various suppliers and a standard injection molding process can be utilized to mold a common mode filter across electrical conductors (e.g., leadframe, leadwires, and so forth).

Thus, in accordance with a preferred embodiment of the present invention, a cost-effective design can be implemented because standard-manufacturing processes may be utilized, which require far fewer alterations to be incorporated into a design versus utilizing a separate common mode filter component. Utilizing a molded ferrite filter across the electrical conductors, in accordance with the method and apparatus of the present invention, can provide even greater EMC performance than utilizing other filter components on the PCB. Additionally, in accordance with the method and apparatus of the present invention, the molded filter can double as a pre-molded tie bar, thereby, in essence “killing two birds with one stone.”

In some sensor designs, such as those utilized in automotive sensors, for example, the leadframe is very long and the possibility exists that individual terminals will flex and an overall portion will not maintain its original shape. A typical approach to resolving this issue involves molding plastic tie bars to prevent flexing and then shearing out the metal tie bars to electrically isolate each conductor. In accordance with the method and apparatus of the present invention, however, such a plastic tie bar can be replaced with a ferrite tie bar that may double as a common mode filter, thereby greatly enhancing the EMC performance and eliminating the need to utilize some of the filtering components on a PCB.

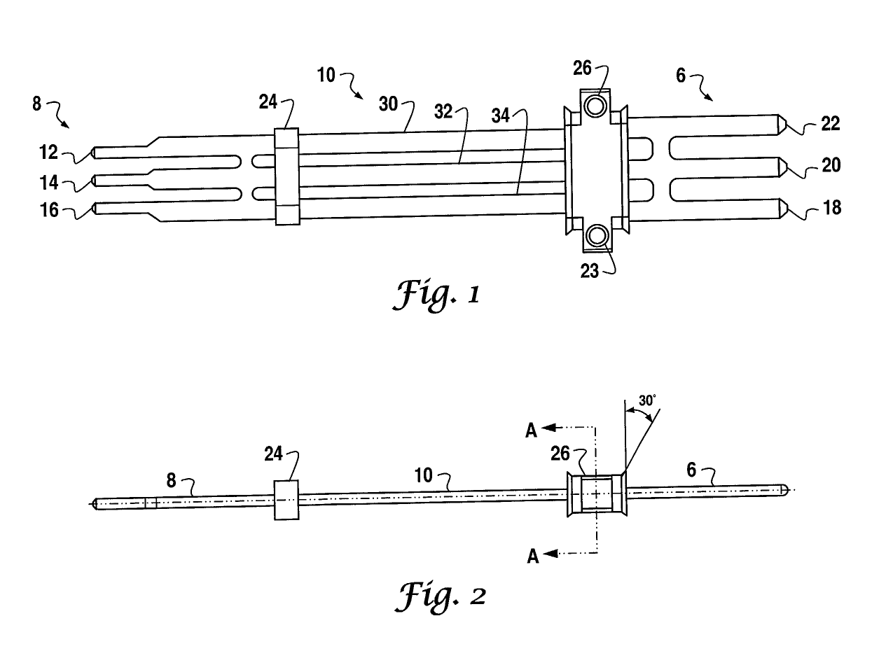

FIG. 1 thus depicts a top view of a leadframe 10, in accordance with a preferred embodiment of the present invention. Note that in FIGS. 1 to 5 herein, like parts are indicated by identical reference numerals. FIGS. 1 to 5 thus present varying views of the same leadframe 10. Leadframe 10 generally comprises a back end 6, which includes tips 18, 20, and 22. Leadframe 10 also includes a front end 8 composed of tips 12, 14, and 16. Leadframe 10 is additionally configured to include three rods 30, 32, and 34, which each may comprise electrical conductors. Thus tips 12 and 22 are respectively formed at the front and back ends 8 and 6 of rod 30. Tips 14 and 20 are respectively formed at the front and back ends 8 and 6 of rod 32. Tips 16 and 18 are respectively formed at the front and back ends 8 and 6 of rod 34.

Leadframe 10 also includes a tie bar 24, which can be configured as a ferrite tie bar (although other configurations are possible), which also functions as a common mode ferrite filter, in accordance with the method and apparatus of the present invention. It can be appreciated that ferrite is but one material example which can be implemented in accordance with the method and apparatus of the present invention. A common mode filter implemented in accordance with the method and apparatus of the present invention may also be configured from materials other than ferrite, although ferrite is generally preferred. Note that reference numeral 23 illustrated in FIG. 1 depicts generally one of a pair of locator holes that can be utilized in a subsequent manufacturing process.

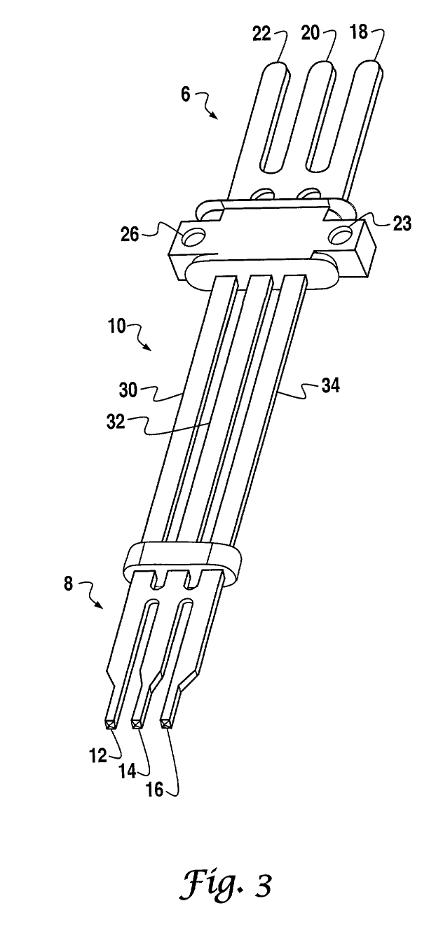

FIG. 2 illustrates a side view of the leadframe 10 illustrated in FIG. 1, in accordance with a preferred embodiment of the present invention. In FIG. 2, a side view of tie bar 24 is indicated along with front end 8 and back end 6. Note that reference numeral 26 illustrates a tie bar that can be utilized to support leadframe 10, which may be, for example, configured from ferrite or other materials. Note that as indicated in FIG. 2, the 30-degree angle generally refers to a mold draft, although other angles are possible.

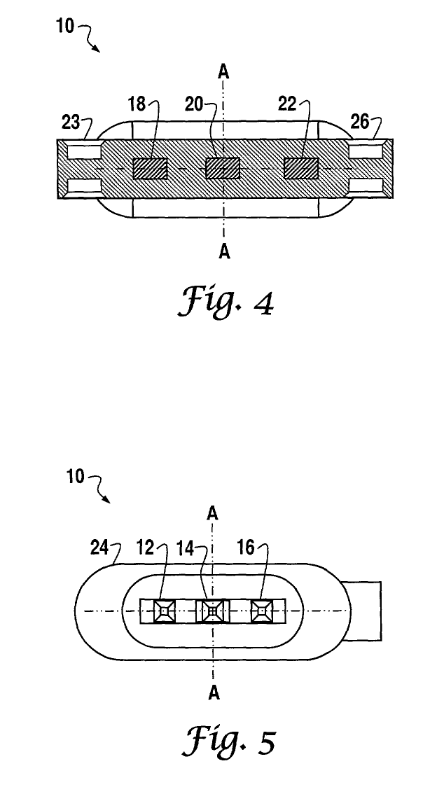

FIG. 3 depicts a pictorial perspective view of the leadframe 10 illustrated in FIGS. 1 and 2, in accordance with a preferred embodiment of the present invention. FIG. 3 thus illustrates rods 30, 32, and 34, along with tips 12,14, and 16 of front end 8 and tips 22, 20, and 18 of back end 6. FIG. 4 illustrates a back view 6 (looking toward front view 8) of leadframe 10 taken along section A-A (shown in FIG. 2) as illustrated in FIGS. 1 to 3, in accordance with a preferred embodiment of the present invention. FIG. 5 depicts a front view 8 (looking toward back view 6) of the leadframe 10 as illustrated in FIGS. 1 to 3, in accordance with a preferred embodiment of the present invention. Again, those skilled in the art will understand that the figures are to be consulted as a whole.

The present invention thus disclosures a method for forming a common mode filter for an electronic sensor and a common mode filter apparatus thereof. A common mode filter can be molded across electrical conductors associated with the electronic sensor to thereby provide an enhanced EMC performance for the electronic sensor. The common mode filter is thus integrated with the electronic sensor rather than implemented as a separate common mode filter component. The common mode filter comprises a ferrite filter molded across the electrical conductors. The electrical conductors themselves can be configured as electrical components such as, for example, a leadframe or leadwires associated with the electronic sensor. Additionally, the common mode filter can be configured as a pre-molded tie bar. Such a pre-molded tie bar may be configured as a ferrite tie bar.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered. For example, it can be appreciated by those skilled in the art that the present invention described herein can apply to automotive sensor applications. The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

The embodiments of an invention in which an exclusive property or right is claimed are defined as follows:

1. A method for forming a common mode filter for an electronic sensor, said method comprising the step of:
molding a common mode filter across electrical conductors associated with said electronic sensor to thereby provide an enhanced electromagnetic compliance performance for said electronic sensor.

2. The method of claim 1 further comprising the step of:
integrating said common mode filter with said electronic sensor to provide an electronic sensor design in which said common mode filter is integrated with said electronic sensor rather than implemented as a separate common mode filter component.

3. The method of claim 1 wherein said common mode filter comprises a ferrite filter molded across said electrical conductors associated with said electronic sensor.

4. The method of claim 1 wherein said electrical conductors form a portion of a leadframe associated with said electronic sensor.

5. The method of claim 1 wherein said electrical conductors comprise at least one leadwire associated with said electronic sensor.

6. The method of claim 1 further comprising the step of:
configuring said common mode filter as a pre-molded tie bar.

7. The method of claim 1 further comprising the step of:
configuring said common mode filter as a ferrite filter molded across said electrical conductors associated with said electronic sensor, such that said ferrite filter comprises a ferrite tie bar.

8. A method for implementing a common mode filter for electronic sensors, said method comprising the step of:
molding a common mode filter across electrical conductors associated with said electronic sensor to thereby provide an enhanced electromagnetic compliance performance for said electronic sensor; and
integrating said common mode filter with said electronic sensor to provide an electronic sensor design in which said common mode filter is integrated with said electronic sensor rather than implemented as a separate common mode filter component.

9. A method for forming a common mode ferrite filter for an electronic sensor, said method comprising the steps of:
molding a common mode ferrite filter across electrical conductors associated with said electronic sensor to thereby provide an enhanced electromagnetic compliance performance for said electronic sensor, wherein said electrical conductors comprise at least one leadwire and a leadframe associated with said electronic sensor; and
integrating said common mode ferrite filter with said electronic sensor to provide an electronic sensor design in which said common mode ferrite filter is integrated with said electronic sensor rather than implemented as a separate common mode ferrite filter component.

10. A method for forming a common mode ferrite filter for an electronic sensor, said method comprising the steps of:
molding a common mode ferrite filter across electrical conductors associated with said electronic sensor to thereby provide an enhanced electromagnetic compliance performance for said electronic sensor, wherein said electrical conductors comprise leadwires and a leadframe associated with said electronic sensor;
configuring said common mode filter as a ferrite filter molded across said electrical conductors associated with said electronic sensor, such that said ferrite filter comprises a ferrite tie bar; and
integrating said common mode ferrite filter with said electronic sensor to provide an electronic sensor design in which said common mode ferrite filter is integrated with said electronic sensor rather than implemented as a separate common mode ferrite filter component.

11. A common mode filter apparatus for an electronic sensor, said apparatus comprising:
a common mode filter molded across electrical conductors associated with said electronic sensor to thereby provide an enhanced electromagnetic compliance performance for said electronic sensor.

12. The apparatus of claim 11 wherein said common mode filter is integrated with said electronic sensor to provide an electronic sensor design in which said common mode filter is integrated with said electronic sensor rather than implemented as a separate common mode filter component.

13. The apparatus of claim 11 wherein said common mode filter comprises a ferrite filter molded across said electrical conductors associated with said electronic sensor.

14. The apparatus of claim 11 wherein said electrical conductors form a portion of a leadframe associated with said electronic sensor.

15. The apparatus of claim 1 wherein said electrical conductors comprise leadwires associated with said electronic sensor.

16. The apparatus of claim 11 wherein said common mode filter is configured as a pre-molded tie bar.

17. The apparatus of claim 11 wherein said common mode filter is configured as a ferrite filter molded across said electrical conductors associated with said electronic sensor, such that said ferrite filter comprises a ferrite tie bar.

18. A common mode filter apparatus for an electronic sensor, said apparatus comprising:
molding a common mode filter across electrical conductors associated with said electronic sensor to thereby provide an enhanced electromagnetic compliance performance for said electronic sensor; and
integrating said common mode filter with said electronic sensor to provide an electronic sensor design in which said common mode filter is integrated with said electronic sensor rather than implemented as a separate common mode filter component.

19. A common mode ferrite filter apparatus for electronic sensors, said apparatus comprising:
a common mode ferrite filter molded across electrical conductors associated with said electronic sensor to thereby provide an enhanced electromagnetic compliance performance for said electronic sensor, wherein said electrical conductors comprise leadwires and a leadframe associated with said electronic sensor; and
wherein said common mode ferrite filter is integrated with said electronic sensor to provide an electronic sensor design in which said common mode ferrite filter is integrated with said electronic sensor rather than implemented as a separate common mode ferrite filter component.

20. A common mode ferrite filter apparatus for an electronic sensor, said apparatus comprising:
a common mode ferrite filter molded across electrical conductors associated with said electronic sensor to thereby provide an enhanced electromagnetic compliance performance for said electronic sensor, wherein said electrical conductors comprise leadwires and a leadframe associated with said electronic sensor;
said common mode filter configured as a ferrite filter molded across said electrical conductors associated with said electronic sensor, such that said ferrite filter comprises a ferrite tie bar; and
wherein said common mode ferrite filter is integrated with said electronic sensor to provide an electronic sensor design in which said common mode ferrite filter is integrated with said electronic sensor rather than implemented as a separate common mode ferrite filter component.

21. The method of claim 1 wherein said electronic sensor is adapted for use as an automotive sensor device.

22. The system of claim 11 wherein said electronic sensor is adapted for use an automotive sensor device.
